(19) United States
(12) Patent Application Publication
(10) Pub. No.: US 2026/0047251 A1
(43) Pub. Date: Feb. 12, 2026

(54) STAMP FOR TRANSFERRING MICRO LIGHT EMITTING DIODE AND METHOD FOR TRANSFERRING MICRO LIGHT EMITTING DIODE USING THE SAME

(71) Applicant: LG DISPLAY CO., LTD., SEOUL (KR)

(72) Inventors: Bongseok Choi, Gimpo-si (KR); DoYoung Kwak, Hanam-si (KR)

(21) Appl. No.: 19/091,929

(22) Filed: Mar. 27, 2025

(30) Foreign Application Priority Data
Aug. 6, 2024 (KR) 10-2024-0104588

(51) Int. Cl. H10H 29/03; H01L 21/67; H10H 29/01

(52) U.S. Cl. CPC H10H 29/03; H01L 21/67144; H10H 29/012

(57) ABSTRACT

A stamp for transferring a micro light emitting diode (LED). The stamp includes a base substrate; a plurality of voltage applying pads disposed on the base substrate; a plurality of mesa structure units disposed on the base substrate; a plurality of mesa electrode units disposed on one surface of each of the plurality of mesa structure units; and a plurality of voltage applying wires connected to each of the plurality of voltage applying pads, in which each of the plurality of mesa electrode units is connected to a different voltage applying wire among the plurality of voltage applying wires. Accordingly, by individually controlling voltages applied to the plurality of mesa structure units to selectively transfer the micro-LEDs, an over-transfer defect may be suppressed.

### CROSS-REFERENCE TO RELATED APPLICATIONS

Pursuant to 35 U.S. C. § 119(a), this application claims the benefit of an earlier filing date and right of priority to Korean Patent Application No. 10-2024-0104588 filed on Aug. 6, 2024, in the Korean Intellectual Property Office, the disclosure of which is incorporated herein by reference in its entirety.

### TECHNICAL FIELD

The present disclosure relates to a stamp for transferring a micro light emitting diode (LED) and a method for transferring a micro-LED using the same.

### BACKGROUND

Display devices are applied to various electronic devices such as televisions, mobile phones, laptops, and tablets.

The display device includes an organic light emitting display (OLED) device that emits light on its own, and a liquid crystal display (LCD) device that requires a separate light source.

Recently, a display device that includes a light emitting diode (LED) is attracting attention as a next-generation display device. Since the light emitting diode is made of an inorganic material rather than an organic material, the light emitting diodes can light up faster than the liquid crystal display device or the organic light emitting display device, has excellent light emitting efficiency, and can display a high-brightness image.

### SUMMARY

According to one example implementation of the present disclosure, there is provided a stamp for transferring a micro light emitting diode (LED), the stamp including: a base substrate; a plurality of voltage applying pads disposed on the base substrate; a plurality of mesa structure units disposed on the base substrate; a plurality of mesa electrode units disposed on one surface of each of the plurality of mesa structure units; and a plurality of voltage applying wires connected to each of the plurality of voltage applying pads, in which each of the plurality of mesa electrode units is connected to a different voltage applying wire among the plurality of voltage applying wires. Accordingly, in some scenarios, by adaptively controlling voltages applied to different mesa structure units among the plurality of mesa structure units to selectively transfer the micro-LEDs, an over-transfer defect may be suppressed.

Other detailed matters of the example implementations are included in the detailed description and the drawings.

The implementations described herein can provide various technical effects.

For example, a micro light emitting diode (LED) may be selectively transferred by adaptively controlling voltages applied to one or more of the plurality of mesa structure units.

As another example, a pick-up state of a micro-LED may be maintained by continuously applying a voltage to a mesa structure unit corresponding to a micro-LED that should not be transferred.

As another example, some implementations can provide a stamp for transferring a micro light emitting diode (LED) capable of minimizing or reducing an over-transfer defect and a method for transferring a micro-LED using the same. An over-transfer defect in which the micro-LED that should not be transferred is transferred may be minimized or reduced.

As another example, some implementations can provide a stamp for transferring a micro-LED capable of improving a transfer rate and a method for transferring a micro-LED using the same. As such, the transfer rate may be improved.

The effects described above are merely examples, and other effects can be achieved by implementations described in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view of an example of a stamp for transferring a micro light emitting diode (LED) according to one example implementation of the present disclosure;

FIG. 2 is a plan view of an example of the stamp for transferring a micro-LED according to one example implementation of the present disclosure;

FIG. 3 is an enlarged view of the example of FIG. 2;

FIG. 4A is a cross-sectional view taken along line A-A′ of the example of FIG. 3;

FIG. 4B is a cross-sectional view taken along line B-B′ of the example of FIG. 3;

FIG. 4C is a cross-sectional view taken along line C-C′ of the example of FIG. 3;

FIG. 4D is a cross-sectional view taken along line D-D′ of the example of FIG. 3;

FIG. 5 is a table illustrating a voltage application logic according to a micro-LED transfer process sequence of the stamp for transferring a micro-LED according to one example implementation of the present disclosure;

FIGS. 6A to 6E are process diagrams of a transfer method using the stamp for transferring a micro-LED according to one example implementation of the present disclosure;

FIG. 7 is a circuit diagram of a stamp for transferring a micro-LED according to another example implementation of the present disclosure;

FIG. 8A is a cross-sectional view taken along line A-A′ of the example of FIG. 7;

FIG. 8B is a cross-sectional view taken along line B-B′ of the example of FIG. 7;

FIG. 8C is a cross-sectional view taken along line C-C′ of the example of FIG. 7;

FIG. 8D is a cross-sectional view taken along line D-D′ of the example of FIG. 7; and

FIG. 9 is a table illustrating the voltage application logic according to a micro-LED transfer process sequence of the stamp for transferring a micro-LED according to another example implementation of the present disclosure.

### DETAILED DESCRIPTION

Advantages and characteristics of implementations of the present disclosure and a method of achieving the advantages and characteristics will be clear by referring to examples described below in detail together with the accompanying drawings. However, implementations of the present disclosure are not limited to the examples disclosed herein but can be implemented in other forms. The example implementations are provided by way of example only so that those skilled in the art can fully understand the disclosures of the present disclosure and the scope of the present disclosure.

The shapes, sizes, ratios, angles, numbers, and the like illustrated in the accompanying drawings for describing the example implementations of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately”or “directly”.

When the relation of a time sequential order is described using the terms such as “after”, “continuously to”, “next to”, and “before”, the order may not be continuous unless the terms are used with the term “immediately”or “directly”.

Although the terms first, second, or the like are used to describe various components, these components are not limited by these terms. These terms are only used to distinguish one component from another. Thus, a first component referred to below may also be a second component within the technical scope of the present disclosure.

In describing components of the present disclosure, terms such as first, second, A, B, (a), or (b) may be used. These terms are only intended to distinguish the component from other components, and the nature, order, sequence, or number of the components are not limited by the terms.

When a component is described as being “connected”, “coupled”, “joined”, or “attached” to another component, it should be understood that that the component can be directly connected, coupled, joined, or attached to that other component, but that other components may also be interposed between the components which can be indirectly connected, coupled, joined, or attached, unless otherwise expressly stated.

When a component or layer is described as “contacting” or “overlapping” another component or layer, it should be understood that the component or layer may directly contact or overlap the other component or layer, but that other components may also be interposed between the components that may indirectly contact or overlap each other, unless specifically stated otherwise.

“At least one” should be understood to include any combination of one or more of the associated components. For example, “at least one of the first, second, and third components” could be understood to include any combination of two or more of the first, second, and third components, as well as the first, second, or third components.

A “first direction”, “second direction”, “third direction”, “X-axis direction”, “Y-axis direction” and “Z-axis direction” should not be interpreted as merely geometric relationships in which the relationship between them is perpendicular to each other, but may mean a broader directionality within the scope in which the configuration of the present disclosure can function functionally.

The features of various implementations of the present disclosure can be partially or entirely adhered to or combined with each other and can be interlocked and operated in technically various ways, and the implementations can be carried out independently of or in association with each other.

Hereinafter, a stamp for transferring micro light emitting diode (LED) and a method for transferring micro light emitting diode (LED) using the same according to example implementations of the present disclosure will be described in detail with reference to accompanying drawings.

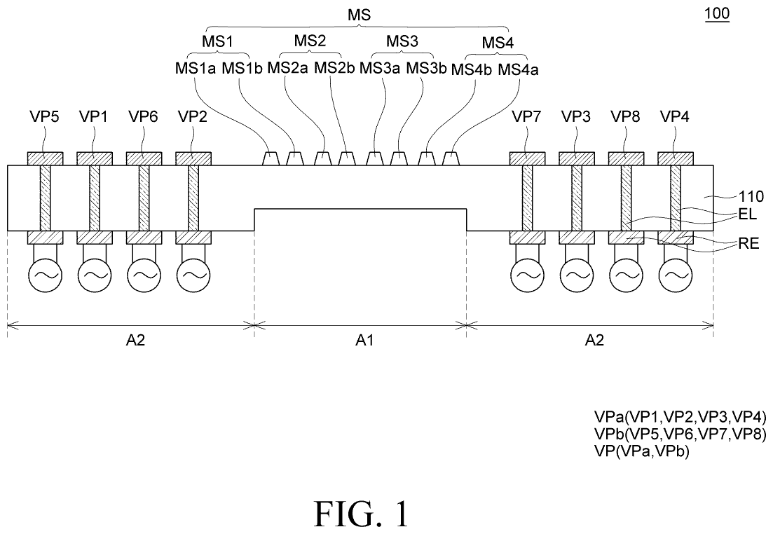

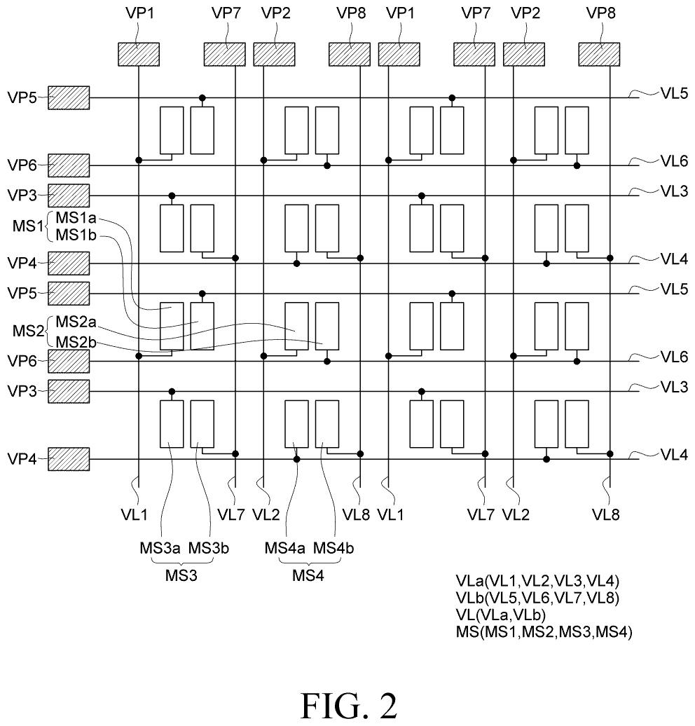

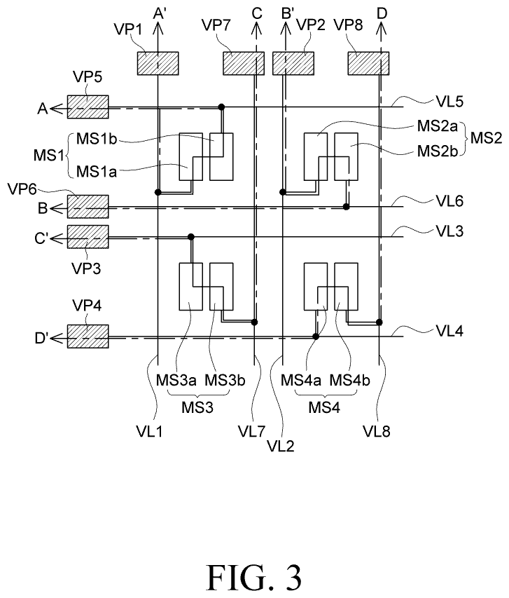

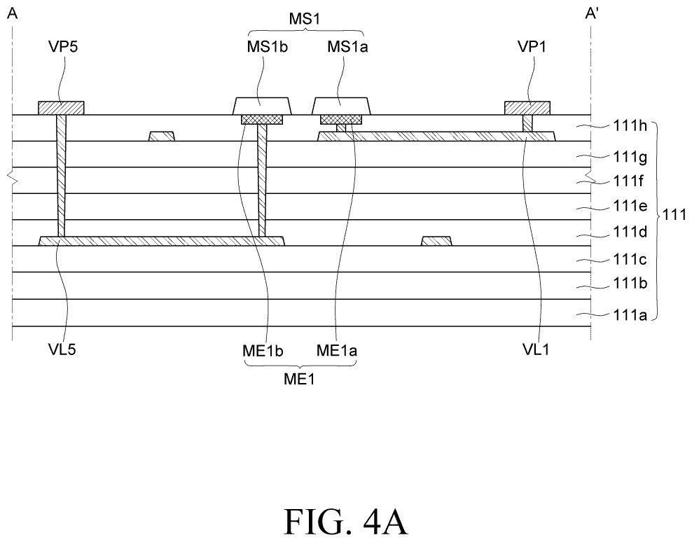

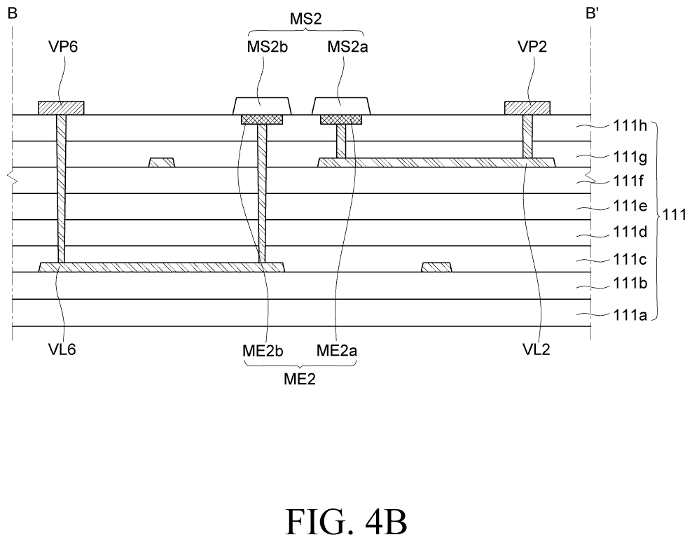

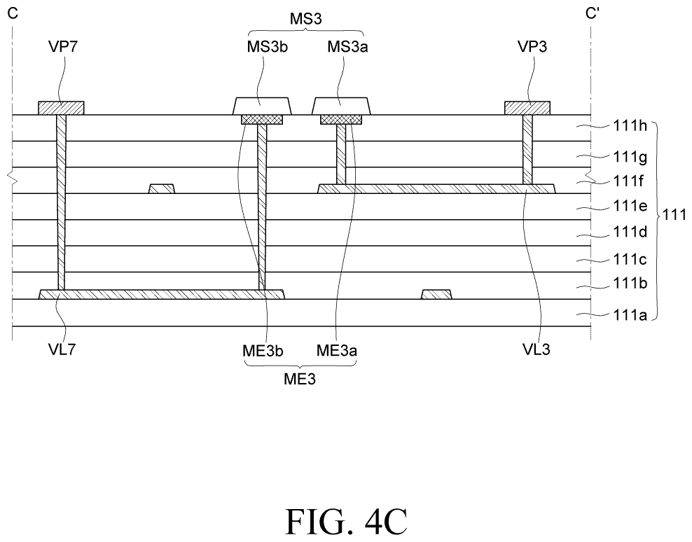

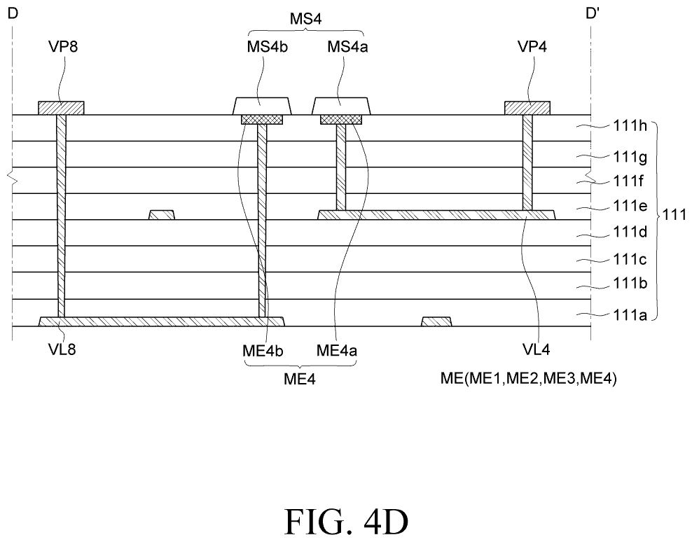

FIG. 1 is a cross-sectional view of a stamp for transferring a micro light emitting diode (LED) according to one example implementation of the present disclosure. FIG. 2 is a plan view of the stamp for transferring a micro-LED according to one example implementation of the present disclosure. FIG. 3 is an enlarged view of FIG. 2. FIG. 4A is a cross-sectional view taken along line A-A′ of FIG. 3. FIG. 4B is a cross-sectional view taken along line B-B′ of FIG. 3. FIG. 4C is a cross-sectional view taken along line C-C′ of FIG. 3. FIG. 4D is a cross-sectional view taken along line D-D′ of FIG. 3. Meanwhile, for convenience of illustration, in FIGS. 4A to 4D, cutting lines A-A′, B-B′, C-C′, and D-D′ are illustrated as not overlapping with a voltage applying wire VL, but the cutting lines A-A′, B-B′, C-C′, and D-D′ of FIGS. 4A to 4D are intended to indicate the same position as the adjacent voltage applying wire VL.

Referring to FIGS. 1 to 4D, a stamp 100 for transferring a micro-LED according to one example implementation of the present disclosure may include a base substrate 110, a plurality of mesa structures units MS, a plurality of mesa electrode units ME, a plurality of voltage applying pads VP, a plurality of electrode wires EL, a plurality of voltage applying wires VL, and a plurality of rear electrodes RE.

First, referring to FIG. 1, the base substrate 110 may be a member that supports other components disposed on the base substrate 110. The base substrate 110 may be made of various materials, such as silicon ceramic and polymer, for example. However, the base substrate 110 is not limited thereto, and may include a plurality of insulating layers as described below.

The base substrate 110 may include areas having different thicknesses. For example, the base substrate 110 may include a first area A1 that is a relatively thin area and a second area A2 that is a relatively thick area. The first area A1 of the base substrate 110 is an area that can move in one direction and can relieve pressure applied to the plurality of mesa structure units MS during a transfer process of the micro-LED. For example, when the plurality of mesa structure units MS come into contact with the micro-LED on a front surface of the base substrate 110, the first area A1 of the base substrate 110 may relieve pressure when the micro-LED comes into contact by allowing the plurality of mesa structure units MS to move in a rear direction, but is not limited thereto.

In the second area A2, the plurality of rear electrodes RE may be disposed on the rear surface of the base substrate 110. The plurality of rear electrodes RE may be connected to the plurality of voltage applying pads VP through the plurality of electrode wires EL to transmit voltage to the plurality of voltage applying pads VP. That is, the plurality of rear electrodes RE may be connected to a voltage source to transmit voltage to the plurality of voltage applying pads VP. As such, the plurality of rear electrodes RE may transmit different voltages to one or more of the plurality of voltage applying wires VL through the plurality of electrode wires EL.

In the first area A1, the plurality of mesa structure units MS may be disposed on the front surface of the base substrate 110. The plurality of mesa structure units MS may protrude from the base substrate 110 and may be joined to the micro-LED to pick up or release the micro-LED, thereby transferring the micro-LED. For example, each of the plurality of mesa structure units MS may pick up or release the micro-LED according to the electrostatic force at the interface between the micro-LED and the plurality of mesa structure units MS. For example, each of the plurality of mesa structure units MS may be configured to pick up and release one micro-LED, but is not limited thereto.

For example, the plurality of mesa structure units MS may include a first mesa structure unit MS1, a second mesa structure unit MS2, a third mesa structure unit MS3, and a fourth mesa structure unit MS4. Hereinafter, examples are described in which the plurality of mesa structure units MS consists of four mesa structure units (MS1, MS2, MS3, MS4), but implementations are not limited thereto.

The plurality of mesa structure units MS may collectively include first mesa structures MS1a, MS2a, MS3a, and MS4a and second mesa structures MS1b, MS2b, MS3b, and MS4b. The first mesa structures MS1a, MS2a, MS3a, and MS4a and the second mesa structures MS1b, MS2b, MS3b, and MS4b may be spaced apart from each other and form one unit to transfer one micro-LED. For example, the first mesa structure unit MS1 consists of the first mesa structure MS1a and second mesa structure MS1b. The second mesa structure unit MS2 consists of the first mesa structure MS2a and second mesa structure MS2b. The third mesa structure unit MS3 consists of the first mesa structure MS3a and second mesa structure MS3b. The fourth mesa structure unit MS4 consists of the first mesa structure MS4a and second mesa structure MS4b.

For example, each of the first mesa structures MS1a, MS2a, MS3a, and MS4a and the second mesa structures MS1b, MS2b, MS3b, and MS4b of the plurality of mesa structure units MS may have a tapered shape, for example, a trapezoidal shape, but is not limited thereto.

In the second area A2, the plurality of voltage applying pads VP may be disposed on the front surface of the base substrate 110. The plurality of voltage applying pads VP may transmit voltages applied from the plurality of rear electrodes RE to the plurality of mesa structure units MS through the plurality of electrode wires EL. In some implementations, each voltage applying pad (VP1, VP2, etc.) may individually apply voltages to different mesa structures.

For example, the plurality of voltage applying pads VP may include a plurality of first voltage applying pads VPa and a plurality of second voltage applying pads VPb that apply different voltages. For example, the plurality of first voltage applying pads VPa may include a first pad VP1, a second pad VP2, a third pad VP3, and a fourth pad VP4. The first pad VP1, the second pad VP2, the third pad VP3, and the fourth pad VP4 may transmit a first voltage to the first mesa structure MS1a of the first mesa structure unit MS1, the first mesa structure MS2a of the second mesa structure unit MS2, the first mesa structure MS3a of the third mesa structure unit MS3, and the first mesa structure MS4a of the fourth mesa structure unit MS4, respectively.

The plurality of second voltage applying pads VPb may include a fifth pad VP5, a sixth pad VP6, a seventh pad VP7, and an eighth pad VP8. The fifth pad VP5, the sixth pad VP6, the seventh pad VP7, and the eighth pad VP8 may transmit a second voltage to the second mesa structure MS1b of the first mesa structure unit MS1, the second mesa structure MS2b of the second mesa structure unit MS2, the second mesa structure MS3b of the third mesa structure unit MS3, and the second mesa structure MS4b of the fourth mesa structure unit MS4, respectively.

Therefore, in the example described above, the first pad VP1 and the fifth pad VP5 may be connected to the first mesa structure unit MS1 (e.g., VP1 connected to MS1a and VP5 connected to MS1b). The second pad VP2 and the sixth pad VP6 may be connected to the second mesa structure unit MS2 (e.g., VP2 connected to MS2a and VP6 connected to MS2b). The third pad VP3 and the seventh pad VP7 may be connected to the third mesa structure unit MS3 (e.g., VP3 connected to MS3a and VP7 connected to MS3b). The fourth pad VP4 and the eighth pad VP8 may be connected to the fourth mesa structure unit MS4 (e.g., VP4 connected to MS4a and VP8 connected to MS4b). However, this is merely an example and implementations are not limited thereto. Further details of the connection relationship between the plurality of mesa structure units MS and the plurality of first voltage applying pads VPa and the plurality of second voltage applying pads VPb will be described in detail with reference to FIG. 2 to be described later.

The plurality of electrode wires EL may be disposed between the plurality of rear electrodes RE and the plurality of voltage applying pads VP. For example, the plurality of electrode wires EL may be disposed to penetrate the base substrate 110, but is not limited thereto.

Referring to FIGS. 2 and 3, the plurality of first voltage pads VPa and the plurality of second voltage pads VPb may be disposed to be spaced apart from each other in the row direction and the column direction, respectively. In this case, the plurality of first voltage pads VPa and the plurality of second voltage pads VPb may be disposed alternately. For example, the plurality of first voltage applying pads VPa and the plurality of second voltage applying pads VPb may be disposed alternately one by one in the row direction. For example, the first pad VP1 which is the first voltage applying pad VPa, the seventh pad VP7 which is the second voltage applying pad VPb, the second pad VP2 which is the first voltage pad VPa, and the eighth pad VP8 which is the second voltage applying pad VPb may be disposed alternately. In addition, the plurality of first voltage applying pads VPa and the plurality of second voltage applying pads VPb may be disposed alternately two by two in the column direction. For example, the fifth pad VP5 and the sixth pad VP6, which are the second voltage applying pads VPb, and the third pad VP3 and the fourth pad VP4, which are the first voltage applying pads VPa, may be alternately disposed, but are not limited thereto.

The plurality of voltage applying wires VL may be disposed to be connected to the plurality of pad electrodes VP and extended in the row and column directions. The plurality of voltage applying wires VL may connect the plurality of voltage applying pads VP and the plurality of mesa structure units MS.

For example, the plurality of voltage applying wires VL may include a plurality of first voltage applying wires VLa connected to the plurality of first voltage applying pads VPa and a plurality of second voltage applying wires VLb connected to the plurality of second voltage applying pads VPb.

The plurality of first voltage applying wires VLa may include a first wire VL1 connected to the first pad VP1, a second wire VL2 connected to the second pad VP2, a third wire VL3 connected to the third pad VP, and a fourth wire VL4 connected to the fourth pad VP4.

The plurality of second voltage applying wires VLb may include a fifth wire VL5 connected to the fifth pad VP5, a sixth wire VL6 connected to the sixth pad VP6, a seventh wire VL7 connected to the seventh pad VP7, and an eighth wire VL8 connected to the eighth pad VP8.

The plurality of first voltage applying wires VLa and the plurality of second voltage applying wires VLb may be alternately disposed in the row direction and the column direction, similar to the plurality of voltage applying pads VP. For example, the plurality of first voltage applying wires VLa that transmit the first voltage in the row direction and the plurality of second voltage applying wires VLb that apply the second voltage may be alternately disposed one by one. For example, the first wire VL1 that is the first voltage applying wire VLa, the seventh wire VL7 that is the second voltage applying wire VLb, the second wire VL2 that is the first voltage applying wire VLa, and the eighth wire VL8 that is the second voltage applying wire VLb may be alternately disposed. In addition, the plurality of first voltage applying wires and the plurality of second voltage applying wires may be alternately disposed two by two in the column direction. For example, the fifth wire VL5 and the sixth wire VL6 which are the second voltage applying wires VLb, and the third wire VL3 and the fourth wire VL4 which are the first voltage applying wires VLa may be disposed alternately, but are not limited thereto.

In this case, the plurality of mesa structure units MS may be disposed between the plurality of intersecting voltage applying wires VL and may be connected to different voltage applying pads VP through different voltage applying wires VL.

For example, referring to FIGS. 4A to 4D, the plurality of mesa electrode units ME may be disposed on one surface of each of the plurality of mesa structure units MS. In these examples, the plurality of mesa electrode units ME may individually receive voltages from different voltage applying pads VP through different voltage applying wires VL.

For example, the plurality of mesa electrode units ME may include a first mesa electrode unit ME1, a second mesa electrode unit ME2, a third mesa electrode unit ME3, and a fourth mesa electrode unit ME4.

The first mesa electrode unit ME1 may be disposed on one surface of the first mesa structure unit MS1, for example, on the rear surface of the first mesa structure unit MS1, so as to form an electrostatic force at the interface between the first mesa structure unit MS1 and the micro-LED.

The second mesa electrode unit ME2 may be disposed on one surface of the second mesa structure unit MS2, for example, on the rear surface of the second mesa structure unit MS2, to form an electrostatic force at the interface between the second mesa structure unit MS2 and the micro-LED.

The third mesa electrode unit ME3 may be disposed on one surface of the third mesa structure unit MS3, for example, on the rear surface of the third mesa structure unit MS3, to form an electrostatic force at the interface between the third mesa structure unit MS3 and the micro-LED.

The fourth mesa electrode unit ME4 may be disposed on one surface of the fourth mesa structure unit MS4, for example, on the rear surface of the fourth mesa structure unit MS4, to form an electrostatic force at the interface between the fourth mesa structure unit MS4 and the micro-LED.

The plurality of mesa electrode units ME may include first mesa electrodes ME1a, ME2a, ME3a, and ME4a and second mesa electrodes ME1b, ME2b, ME3b, and ME4b, respectively. The first mesa electrodes ME1a, ME2a, ME3a, and ME4a and the second mesa electrodes ME1b, ME2b, ME3b, and ME4b may be disposed on different mesa structures among the plurality of mesa structure units MS and may be spaced apart from each other. For example, the first mesa electrodes ME1a, ME2a, ME3a, and ME4a may be disposed on one surface of the first mesa structures MS1a, MS2a, MS3a, and MS4a, and the second mesa electrodes ME1b, ME2b, ME3b, and ME4b may be disposed on one surface of the second mesa structures MS1b, MS2b, MS3b, and MS4b.

The first mesa electrodes ME1a, ME2a, ME3a, and ME4a and the second mesa electrodes ME1b, ME2b, ME3b, and ME4b are connected to different voltage applying pads VP and voltage applying wires VL so that different voltages may be applied thereto. For example, the first mesa electrodes ME1a, ME2a, ME3a, and ME4a are connected to the first voltage applying pad VPa through the first voltage applying wire VLa so that the first voltage may be applied thereto. The second mesa electrodes ME1b, ME2b, ME3b, and ME4b are connected to the second voltage applying pad VPb through the second voltage applying wire VLb so that the second voltage may be applied thereto.

That is, the first mesa electrode unit ME1 disposed on one surface of the first mesa structure unit MS1 may be connected to the first wire VL1 and the fifth wire VL5 to receive the first voltage and the second voltage.

The second mesa electrode unit ME2 disposed on one surface of the second mesa structure unit MS2 may be connected to the second wire VL2 and the sixth wire VL6 to receive the first voltage and the second voltage.

The third mesa electrode unit ME3 disposed on one surface of the third mesa structure unit MS3 may be connected to the third wire VL3 and the seventh wire VL7 to receive the first voltage and the second voltage.

The fourth mesa electrode unit ME4 disposed on one surface of the fourth mesa structure unit MS4 may be connected to the fourth wire VL4 and the eighth wire VL8 to receive the first voltage and the second voltage.

For example, the first voltage and the second voltage may be direct current voltages or alternating current voltages. The first voltage and the second voltage may have the same magnitude of voltage but different signs. However, this is not limited thereto, and for example, the signs may be the same but different in magnitude of voltage.

In some implementations, the base substrate 110 may include a plurality of insulating layers that insulates different voltage applying wires VL so that each of the plurality of mesa electrode units ME may individually receive voltage through respective voltage applying wires VL. For example, the plurality of insulating layers 111 may include at least a first insulating layer 111a, a second insulating layer 111b on the first insulating layer 111a, a third insulating layer 111c on the second insulating layer 111b, a fourth insulating layer 111d on the third insulating layer 111c, a fifth insulating layer 111e on the fourth insulating layer 111d, a sixth insulating layer 111f on the fifth insulating layer 111e, a seventh insulating layer 111g on the sixth insulating layer 111f, and an eighth insulating layer 111h on the seventh insulating layer 111h.

Referring to FIGS. 4A to 4D, the first insulating layer 111a may be disposed on the eighth wire VL8. The first insulating layer 111a may insulate the eighth wire VL8 and the seventh wire VL7.

The eighth wire VL8 may connect the eighth pad VP8 and the second mesa electrode ME4b of the fourth mesa electrode unit ME4 through contact holes of at least the first insulating layer 111a, the second insulating layer 111b, the third insulating layer 111c, the fourth insulating layer 111d, the fifth insulating layer 111e, the sixth insulating layer 111f, the seventh insulating layer 111g and the eighth insulating layer 111h.

The seventh wire VL7 may be disposed on the eighth wire VL8 and the first insulating layer 111a. The seventh wire VL7 may connect the seventh pad VP7 and the second mesa electrode ME3b of the third mesa electrode unit ME3 through contact holes of at least the second insulating layer 111b, the third insulating layer 111c, the fourth insulating layer 111d, the fifth insulating layer 111e, the sixth insulating layer 111f, the seventh insulating layer 111g and the eighth insulating layer 111h.

The second insulating layer 111b may be disposed on the seventh wire VL7 and the first insulating layer 111a. The second insulating layer 111b may insulate the seventh wire VL7 and the sixth wire VL6.

The sixth wire VL6 may be disposed on the second insulating layer 111b. The sixth wire VL6 may connect the sixth pad VP6 and the second mesa electrode ME2b of the second mesa electrode unit ME2 through contact holes of at least the third insulating layer 111c, the fourth insulating layer 111d, the fifth insulating layer 111e, the sixth insulating layer 111f, the seventh insulating layer 111g and the eighth insulating layer 111h.

The third insulating layer 111c may be disposed on the sixth wire VL6 and the second insulating layer 111b. The third insulating layer 111c may insulate the sixth wire VL6 and the fifth wire VL5.

The fifth wire VL5 may be disposed on the third insulating layer 111c. The fifth wire VL5 may connect the fifth pad VP5 and the second mesa electrode ME1b of the first mesa electrode unit ME1 through contact holes of at least the fourth insulating layer 111d, the fifth insulating layer 111e, the sixth insulating layer 111f, the seventh insulating layer 111g and the eighth insulating layer 111h.

The fourth insulating layer 111d may be disposed on the fifth wire VL5 and the third insulating layer 111c. The fourth insulating layer 111d may insulate the fifth wire VL5 and the fourth wire VL4.

The fourth wire VL4 may be disposed on the fourth insulating layer 111d. The fourth wire VL4 may connect the fourth pad VP4 and the first mesa electrode ME4a of the fourth mesa electrode unit ME4 through contact holes of at least the fifth insulating layer 111e, the sixth insulating layer 111f, the seventh insulating layer 111g and the eighth insulating layer 111h.

The fifth insulating layer 111e may be disposed on the fourth wire VL4 and the fourth insulating layer 111d. The fifth insulating layer 111e may insulate the fourth wire VL4 and the third wire VL3.

The third wire VL3 may be disposed on the fifth insulating layer 111e. The third wire VL3 may connect the third pad VP3 and the first mesa electrode ME3a of the third mesa electrode unit ME3 through the contact holes of at least the sixth insulating layer 111f, the seventh insulating layer 111g and the eighth insulating layer 111h.

The sixth insulating layer 111f may be disposed on the third wire VL3 and the fifth insulating layer 111e. The sixth insulating layer 111f may insulate the third wire VL3 and the second wire VL2.

The second wire VL2 may be disposed on the sixth insulating layer 111f. The second wire VL2 may connect the second pad VP2 and the first mesa electrode ME2a of the second mesa electrode unit ME2 through the contact hole of at least the seventh insulating layer 111g and the eighth insulating layer 111h.

The seventh insulating layer 111g may be disposed on the second wire VL2 and the sixth insulating layer 111f. The seventh insulating layer 111g may insulate the second wire VL2 and the first wire VL1.

The first wire VL1 may be disposed on the seventh insulating layer 111g. The first wire VL1 may connect the first pad VP1 and the first mesa electrode ME1a of the second mesa electrode unit ME1 through the contact hole of the eighth insulating layer 111h.

The eighth insulating layer 111h may be disposed on the first wire VL1 and the seventh insulating layer 111g. The eighth insulating layer 111h may insulate the first wire VL1 and the components above the first wire VL1.

The plurality of insulating layers 111 may be made of an inorganic insulating material. For example, the plurality of insulating layers 111 may be made of silicon oxide SiOx or silicon nitride SiNx, but are not limited thereto, and may also be made of an organic insulating material.

For example, the stamp 100 for transferring a micro-LED according to one example implementation of the present disclosure may pick up the micro-LED once and then release the micro-LED onto the display panel four times. Accordingly, the stamp 100 for transferring a micro-LED according to one example implementation of the present disclosure may include at least four mesa structure units MS and mesa electrode units ME disposed on one surface of the four mesa structure units MS. In addition, the four mesa electrode units ME may include four first voltage applying pads VPa connected to the first mesa electrodes ME1a, ME2a, ME3a, and ME4a and four second voltage applying pads VPb connected to the second mesa electrodes ME1b, ME2b, ME3b, and ME4b. That is, the stamp 100 for transferring a micro-LED according to one example implementation of the present disclosure may include at least eight voltage applying pads VP and eight voltage applying wires VL. That is, FIG. 3 may be a drawing illustrating the minimum unit that constitutes the circuit of the stamp 100 for transferring a micro-LED according to one example implementation of the present disclosure.

However, FIG. 3 is only an example, and for example, when the stamp 100 for transferring a micro-LED is set to release the micro-LED n times per one pickup, the minimum unit may include n mesa structure units MS, n mesa electrode units ME, 2n voltage applying pads VP, and 2n voltage applying wires VL.

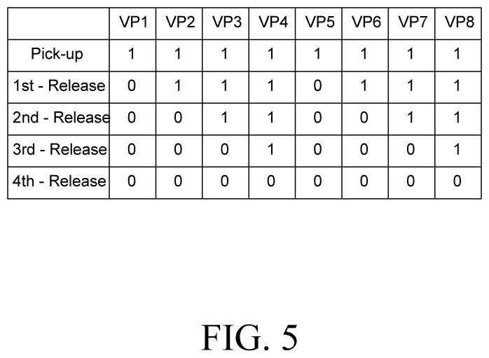

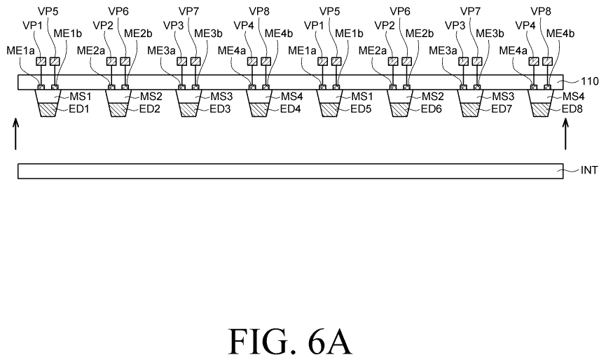

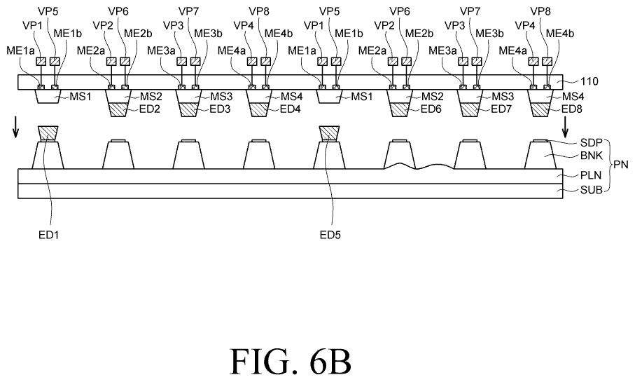

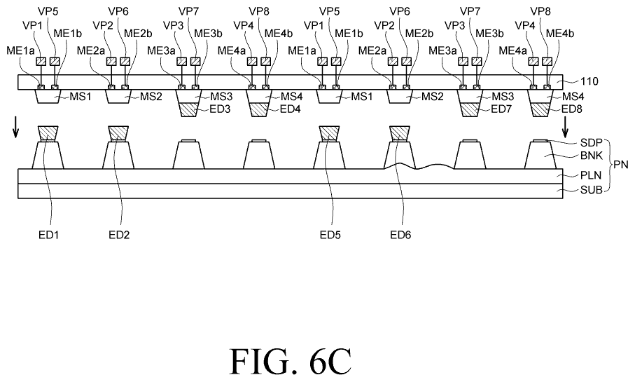

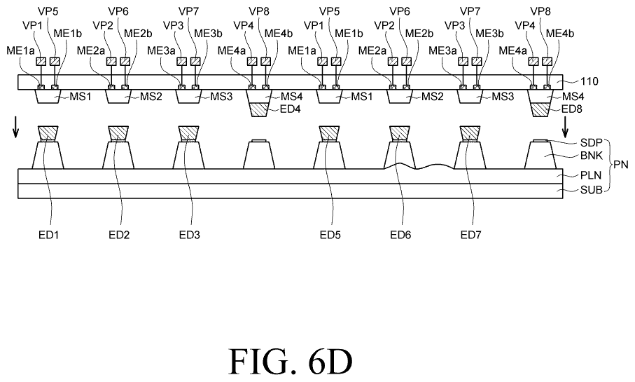

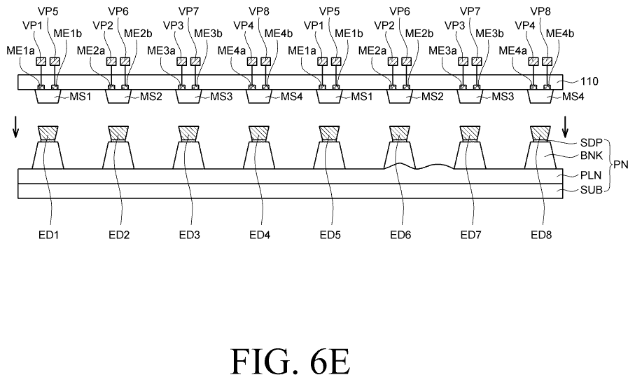

FIG. 5 is a table illustrating a voltage application logic according to a micro-LED transfer process sequence of the stamp for transferring a micro-LED according to one example implementation of the present disclosure. FIGS. 6A to 6E are process diagrams of a transfer method using the stamp for transferring a micro-LED according to one example implementation of the present disclosure. In FIG. 5, a case where voltage is applied to a plurality of voltage applying pads VP is indicated as 1, and a case where voltage is not applied is indicated as 0. For convenience of illustration, the plurality of mesa structure units MS among the configurations of a stamp 100 for transferring a micro-LED are not illustrated as being divided into the first mesa structures MS1a, MS2a, MS3a, and MS4a and the second mesa structures MS1b, MS2b, MS3b, and MS4b, but are illustrated as one unit, and the plurality of voltage applying pads PD are illustrated at arbitrary positions to indicate a connection structure with the plurality of mesa electrode units ME.

Referring to FIGS. 5 and 6A, a pick-up process of a micro-LED ED disposed on an interposer INT may be performed by applying voltage to the plurality of mesa structure units MS. However, the present disclosure is not limited thereto, and a process of picking up the micro-LED ED disposed on a wafer may also be performed.

For example, each of the first mesa structure unit MS1, the second mesa structure unit MS2, the third mesa structure unit MS3, and the fourth mesa structure unit MS4 may be positioned to correspond to a first micro-LED ED1, a second micro-LED ED2, a third micro-LED ED3, a fourth micro-LED ED4, a fifth micro-LED ED5, a sixth micro-LED ED6, a seventh micro-LED ED7, and an eighth micro-LED ED8, respectively. Next, by applying voltage to the first pad VP1 and the fifth pad VP5 connected to the first mesa structure unit MS1, the second pad VP2 and the sixth pad VP6 connected to the second mesa structure unit MS2, the third pad VP3 and the seventh pad VP7 connected to the third mesa structure unit MS3, and the fourth pad VP4 and the eighth pad VP8 connected to the fourth mesa structure unit MS4, the first micro-LED ED1, the second micro-LED ED2, the third micro-LED ED3, the fourth micro-LED ED4, the fifth micro-LED ED5, the sixth micro-LED ED6, the seventh micro-LED ED7, and the eighth micro-LED ED8 may be picked up in batches.

Meanwhile, the first micro-LED ED1, the second micro-LED ED2, the third micro-LED ED3, the fourth micro-LED ED4, the fifth micro-LED ED5, the sixth micro-LED ED6, the seventh micro-LED ED7, and the eighth micro-LED ED8 may have a vertical structure, but are not limited thereto.

Next, referring to FIGS. 5 and 6B, by adaptively controlling whether different voltages are applied to one or more of the plurality of mesa electrode units ME through the plurality of voltage applying pads VP, the micro-LED ED may be selectively transferred onto the display panel PN. First, a 1st-Release process may be performed. In the 1st-Release process, the voltage is cut off only to the first mesa structure unit MS1, so that the first micro-LED ED1 and the fifth micro-LED ED5 may be transferred onto the display panel PN. That is, the voltages of the first pad VP1 and the fifth pad VP5, which apply voltage to the first mesa structure unit MS1 through the first mesa electrode unit ME1, may be cut off. In this case, a voltage may be continuously maintained on the mesa structure unit MS except for the first mesa structure unit MS1. That is, a voltage may be continuously applied to the second pad VP2 and the sixth pad VP6 connected to the second mesa structure unit MS2, the third pad VP3 and the seventh pad VP7 connected to the third mesa structure unit MS3, and the fourth pad VP4 and the eighth pad VP8 connected to the fourth mesa structure unit MS4. Accordingly, the micro-LEDs ED except for the first micro-LED ED1 and the fifth micro-LED ED5 may maintain a picked-up state.

Meanwhile, some areas of a planarization layer PLN disposed on the substrate SUB may not have a flat surface. For example, an area adjacent to a bank BNK where the sixth micro-LED ED6 is to be disposed may not be flat. In this case, since voltage is continuously applied to the second mesa structure unit MS2, the sixth micro-LED ED6 may be maintained in a picked-up state and may not be released in the 1st-Release process.

Meanwhile, the first micro-LED ED1 and the fifth micro-LED ED5 may be disposed on a solder pattern SDP disposed on the bank BNK of the display panel PN. For example, the micro-LED ED may be fixed on the bank BNK by eutectic bonding with the solder pattern SDP at the same time as being released, but is not limited thereto.

Next, referring to FIGS. 5 and 6C, a 2nd-Release process may be performed. In the 2nd-Release process, the voltage of the second mesa structure unit MS2 may be removed so that the second micro-LED ED2 and the sixth micro-LED ED6 may be transferred onto the display panel PN. That is, the voltages of the second pad VP2 and the sixth pad VP6, which apply voltage to the second mesa structure unit MS2 through the second mesa electrode unit ME2, may be cut off. In this case, the voltage may be continuously applied to the mesa structure units MS except for the first mesa structure unit MS1 and the second mesa structure unit MS2. That is, voltage may be continuously applied to the third pad VP3 and the seventh pad VP7 connected to the third mesa structure unit MS3, and the fourth pad VP4 and the eighth pad VP8 connected to the fourth mesa structure unit MS4. Accordingly, the micro-LEDs ED excluding the first micro-LED ED1, the second micro-LED ED2, the fifth micro-LED ED5, and the sixth micro-LED ED6 may maintain the picked-up state during the 2nd-Release process.

Meanwhile, in the table of FIG. 5, it is described that voltage is not applied to the first pad VP1 and the fifth pad VP5 during the 2nd-Release process, but this is not limited thereto. For example, during the 2nd-Release process, voltage may be applied again to the first pad VP1 and the fifth pad VP5 to which voltage has been cut off in the 1st-Release process. For example, there may be a micro-LED ED that is not transferred during the 1st-Release process due to a process error. When such an un-transferred micro-LED ED is transferred during the 2nd-Release process, it is inevitable that the micro-LED will be disposed to be misaligned from the normal position. Accordingly, by re-applying voltage to the first pad VP1 and the fifth pad VP5 after the 1st-Release process so that the un-transferred micro-LED ED may be maintained in a state of being picked up by the first mesa structure unit MS1, a defect in which the un-transferred micro-LED ED in the 1st-Release process is incorrectly transferred in the 2nd-Release process may be suppressed, but is not limited thereto.

Next, referring to FIG. 5 and FIG. 6D, a 3rd-Release process may be performed. In the 3rd-Release process, the voltage of the third mesa structure unit MS3 is removed, so that the third micro-LED ED3 and the seventh micro-LED ED7 may be transferred onto the display panel PN. The voltages of the third pad VP3 and the seventh pad VP7, which apply voltage to the third mesa structure unit MS3 through the third mesa electrode unit ME3, may be cut off. In this case, the voltage may be continuously applied to the fourth mesa structure unit MS4 excluding the first mesa structure unit MS1, the second mesa structure unit MS2, and the third mesa structure unit MS3. That is, the voltage may be continuously applied to the fourth pad VP4 and the eighth pad VP8 connected to the fourth mesa structure unit MS4. Accordingly, the micro-LEDs ED excluding the first micro-LED ED1, the second micro-LED ED2, the third micro-LED ED3, the fifth micro-LED ED5, the sixth micro-LED ED6, and the seventh micro-LED ED7 may maintain the picked-up state during the 3rd-Release process.

Meanwhile, in the table of FIG. 5, it is described that voltage is not applied to the second pad VP2 and the sixth pad VP6 during the 3rd-Release process, but this is not limited thereto. For example, during the 3rd-Release process, the voltage may be applied again to the second pad VP2 and the sixth pad VP6 to which the voltage has been cut off in the 2nd-Release process. For example, there may be a micro-LED ED that is not transferred in the 2nd-Release process due to the process error. When such an un-transferred micro-LED ED is transferred during the 3rd-Release process, it is inevitable that the micro-LED will be disposed to be misaligned from the normal position. Accordingly, by re-applying voltage to the second pad VP2 and the sixth pad VP6 after the 2nd-Release process so that the un-transferred micro-LED ED can be maintained in the state picked up by the second mesa structure unit MS2, a defect in which the un-transferred micro-LED ED in the 2nd-Release process is incorrectly transferred in the 3rd-Release process may be suppressed, but is not limited thereto.

Similarly, during the 3rd-Release process, the voltage may be continuously applied to the first pad VP1 and the fifth pad VP5 to which the voltage has been reapplied in the 2nd release process. Accordingly, the un-transferred micro-LED ED in the 1st-Release process may be maintained in a state of being picked up by the first mesa structure unit MS1. Accordingly, a defect in which the un-transferred micro-LED ED in the 1st-Release process is incorrectly transferred in the 3rd-Release process may be suppressed, but is not limited thereto.

Finally, referring to FIGS. 5 and 6E, the transfer process may be completed by performing a 4th-Release process. In the 4th-Release process, the voltage of the fourth mesa structure unit MS4 is removed, thereby transferring the fourth micro-LED ED4 and the eighth micro-LED ED8 onto the display panel PN, thereby completing the transfer process. That is, the voltages of the fourth pad VP4 and the eighth pad VP8, which apply voltage to the fourth mesa structure unit MS4 through the fourth mesa electrode unit ME4, may be cut off.

Meanwhile, in the table of FIG. 5, it is described that voltage is not applied to the third pad VP3 and the seventh pad VP7 during the 4th-Release process, but this is not limited thereto. For example, during the 4th-Release process, the voltage may be applied again to the third pad VP3 and the seventh pad VP7 to which voltage has been cut off in the 3rd-Release process. For example, there may be a micro-LED ED that is not transferred in the 3rd-Release process due to a process error. When such an un-transferred micro-LED ED is transferred during the 4th-Release process, it is inevitable that the micro-LED will be disposed to be misaligned from the normal position. Accordingly, by re-applying voltage to the third pad VP3 and the seventh pad VP7 after the 3rd-Release process so that the un-transferred micro-LED ED can be maintained in a state of being picked up by the third mesa structure unit MS3, a defect in which the un-transferred micro-LED ED in the 3rd-Release process is incorrectly transferred in the 4th-Release process may be suppressed, but is not limited thereto.

Similarly, during the 4th-Release process, the voltage may be continuously applied to the first pad VP1 and the fifth pad VP5 to which the voltage has been reapplied in the 2nd release process. Accordingly, the un-transferred micro-LED ED in the 1st-Release process may be maintained in a state of being picked up by the first mesa structure unit MS1. Accordingly, a defect in which the un-transferred micro-LED ED in the 1st-Release process is incorrectly transferred in the 4th-Release process may be suppressed, but is not limited thereto.

In addition, during the 4th-Release process, voltage may be continuously applied to the second pad VP2 and the sixth pad VP6 to which voltage has been reapplied in the 3rd-Release process. Accordingly, the un-transferred micro-LED ED in the 2nd release process may be maintained in a state of being picked up by the second mesa structure unit MS2. Accordingly, a defect in which the un-transferred micro-LED ED in the 2nd release process is incorrectly transferred in the 4th-Release process may be suppressed, but is not limited thereto.

The stamp for transferring a micro-LED may pick up the plurality of LEDs in batches and then sequentially transfer the plurality of LEDs onto the bank of the display panel several times. For example, the voltage may be applied to the mesa structure unit of the stamp for transferring a micro-LED to pick up or release the micro-LED using an electrostatic force at the interface between the micro-LED and the mesa structure unit. For example, the plurality of mesa electrode units disposed on the plurality of mesa structure units may be connected in parallel so that the voltage applied to the plurality of mesa electrode units may be uniformly applied or not applied. However, in this case, since the voltage applied to the mesa electrode units is cut off at once, an over-transfer defect may occur in which even micro-LEDs that should not be transferred are transferred. Such an over-transfer defect may be a greater problem, especially when the flatness of the display panel is reduced.

For example, after the micro-LEDs are picked up in batches, some of the micro-LEDs may be positioned between the banks rather than on the upper portions of the banks in the picked-up state. In this case, only the micro-LEDs positioned on the banks in the picked-up state are released, and the other micro-LEDs should be positioned so as to be disposed on the banks in the next release process and then transferred. However, when the voltage to the mesa electrode units is cut off at once, all LEDs, that is, micro-LEDs that should not be released, may also be released. In particular, when the upper surface of the display panel is not flat, the upper surface may be similar to the height of the bank even though it is an area where the bank is not disposed. In other words, since the distance between the micro-LED in the picked-up state and the display panel is relatively close, the micro-LEDs that should not be released may be released and come into contact with the display panel relatively easily. In this way, the flatness of the display panel may have a significant effect on an over-transfer defect. In particular, when the micro-LED is released even though the micro-LED is not in the order in which the micro-LED is released, it is inevitable that the micro-LED will be disposed to be misaligned from the normal position. Since the micro-LED incorrectly transferred in this way cannot be reused, the over-transfer defect is a problem directly related to the transfer rate.

Accordingly, the height of the bank of the display panel may be adjusted to improve the over-transfer defect. For example, by increasing the height of the bank, the gap with the micro-LED to be disposed on the bank may be adjusted, thereby suppressing the over-transfer defect. However, as the height of the bank is increased, it may be difficult to control the width of the bank. For example, the gap between adjacent banks may become narrower. In this case, there is a concern that the mesa structure unit may interfere with the adjacent bank during the micro-LED transfer process. Therefore, there are limitations to this method as well.

Accordingly, in the stamp 100 for transferring a micro-LED according to one example implementation of the present disclosure, the plurality of voltage applying wires VL and the plurality of voltage applying pads VP are individually connected to the plurality of mesa electrode units ME so that voltage may be applied individually to each of the mesa electrode units ME. In general, by selectively controlling whether voltage is applied to one or more of the plurality of mesa electrode units ME, the micro-LED ED may be selectively transferred. For example, voltage may be applied to all of the plurality of mesa electrode units ME so that the micro-LEDs ED may be picked up in batches. Subsequently, the voltage may be selectively cut off only to the mesa electrode unit ME of the specific mesa structure unit MS that is joined to the micro-LED ED to be released. For example, the voltage may be continuously applied only to the mesa electrode unit ME that is joined to the micro-LED ED excluding the micro-LED ED to be released. Accordingly, since the electrostatic force between the micro-LED ED that should not be released and the mesa structure unit MS is maintained, the micro-LED ED that should not be released may maintain a picked-up state. As such, the stamp 100 for transferring a micro-LED according to one example implementation of the present disclosure may minimize or reduce the over-transfer defect in which the micro-LED ED that should not be released is transferred, and may ensure that only the micro-LED ED that matches the transfer order is released to the display panel PN. Therefore, the stamp 100 for transferring a micro-LED according to one example implementation of the present disclosure may improve the transfer rate regardless of the flatness of the display panel PN.

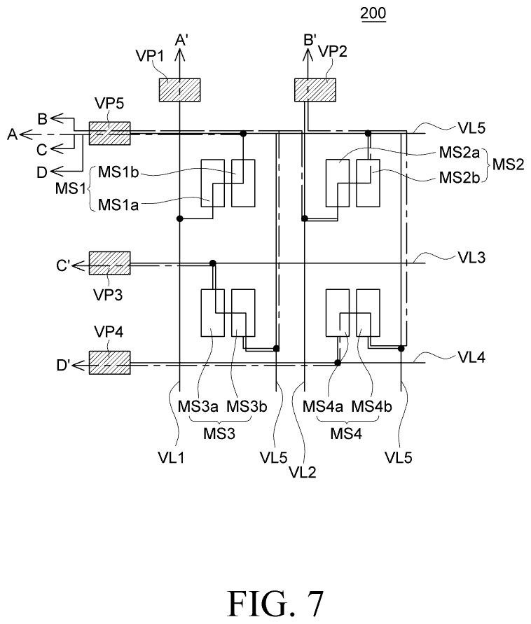

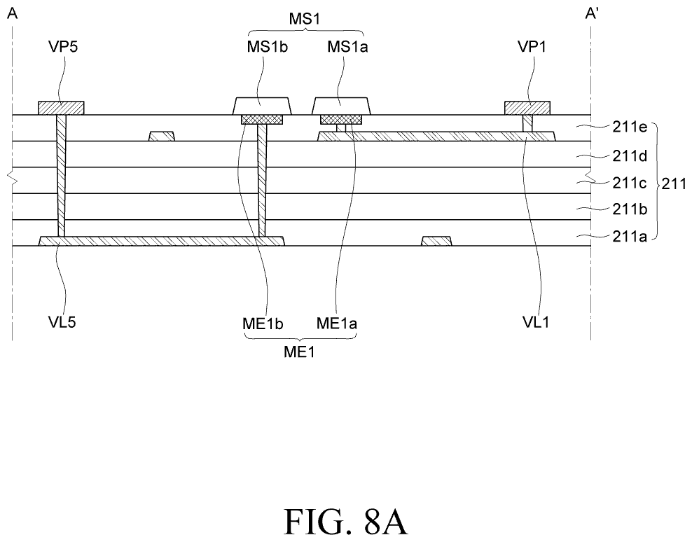

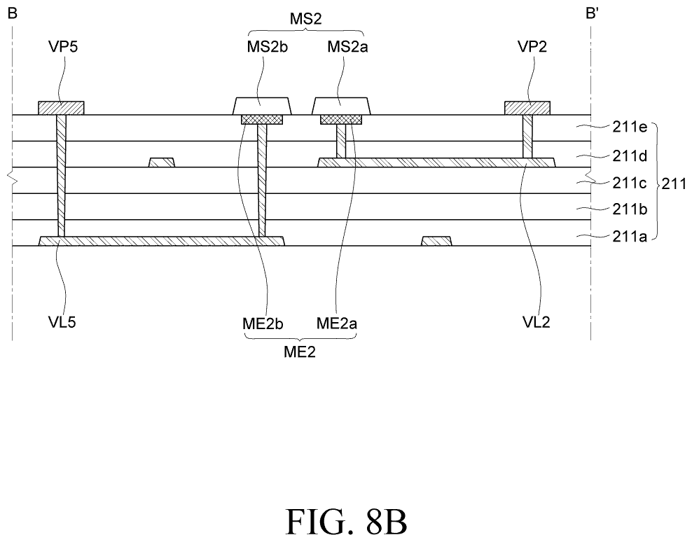

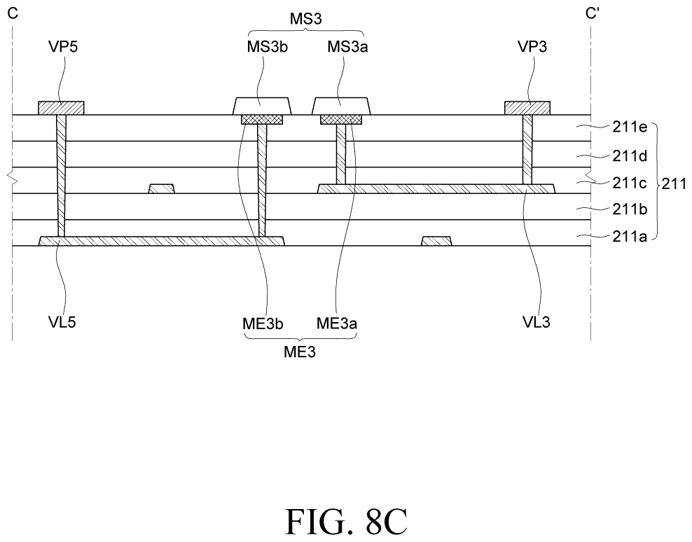

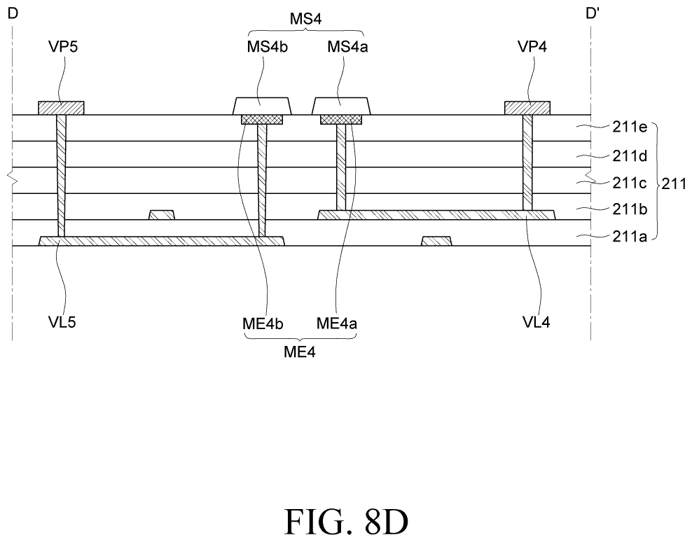

FIG. 7 is a circuit diagram of a stamp for transferring a micro-LED according to another example implementation of the present disclosure. FIG. 8A is a cross-sectional view taken along line A-A′ of FIG. 7. FIG. 8B is a cross-sectional view taken along line B-B′ of FIG. 7. FIG. 8C is a cross-sectional view taken along line C-C′ of FIG. 7. FIG. 8D is a cross-sectional view taken along line D-D′ of FIG. 7. Meanwhile, for convenience of illustration, in FIGS. 8A to 8D, the cut lines of A-A′, B-B′, C-C′, and D-D′ are illustrated as not overlapping with the voltage applying wire VL, but the cut lines of A-A′, B-B′, C-C′, and D-D′ of FIGS. 8A to 8D are intended to indicate the same position as the adjacent voltage applying wire VL. In FIGS. 7 to 8D, compared with the stamp 100 for transferring a micro-LED of FIGS. 1 to 6E, only a second voltage applying pad VPb, a second voltage applying wire VLb, and a plurality of insulating layers 211 are different, and the other components are substantially the same, so a duplicate description is omitted.

Referring to FIG. 7, the plurality of voltage applying pads VP may include the plurality of first voltage applying pads VPa and the plurality of second voltage applying pads VPb that apply different voltages. For example, the plurality of first voltage applying pads VPa may include a first pad VP1, a second pad VP2, a third pad VP3, and a fourth pad VP4. The first pad VP1, the second pad VP2, the third pad VP3, and the fourth pad VP4 may transmit the first voltage to the first mesa structure MS1a of the first mesa structure unit MS1, the first mesa structure MS2a of the second mesa structure unit MS2, the first mesa structure MS3a of the third mesa structure unit MS3, and the first mesa structure MS4a of the fourth mesa structure unit MS4, respectively.

The plurality of second voltage applying pads VPb may include only the fifth pad VP5. The fifth pad VP5 may transmit the second voltage to the second mesa structure MS1b of the first mesa structure unit MS1, the second mesa structure MS2b of the second mesa structure unit MS2, the second mesa structure MS3b of the third mesa structure unit MS3, and the second mesa structure MS4b of the fourth mesa structure unit MS4. That is, the fifth pad VP5 is commonly connected to the second mesa structure MS1b of the first mesa structure unit MS1, the second mesa structure MS2b of the second mesa structure unit MS2, the second mesa structure MS3b of the third mesa structure unit MS3, and the second mesa structure MS4b of the fourth mesa structure unit MS4 so as to transmit (e.g., simultaneously transmit) the second voltage, but is not limited thereto.

That is, the first pad VP1 and the fifth pad VP5 may be connected to the first mesa structure unit MS1. The second pad VP2 and the fifth pad VP5 may be connected to the second mesa structure unit MS2. The third pad VP3 and the fifth pad VP5 may be connected to the third mesa structure unit MS3. The fourth pad VP4 and the fifth pad VP5 may be connected to the fourth mesa structure unit MS4, but are not limited thereto. That is, the second mesa structure MS1b of the first mesa structure unit MS1, the second mesa structure MS2b of the second mesa structure unit MS2, the second mesa structure MS3b of the third mesa structure unit MS3, and the second mesa structure MS4b of the fourth mesa structure unit MS4 may share the fifth pad VP5, but is not limited thereto.

Meanwhile, the plurality of first voltage pads VPa may be disposed to be spaced apart from each other in the row direction and the column direction. In this case, in FIG. 7, it is illustrated that the fifth pad VP5 of the plurality of second voltage pads VPb is disposed in the column direction and is disposed relatively adjacent to the first pad VP1 of the first pad VP1 and the third pad VP3, but is not limited thereto, and may be disposed relatively adjacent to the third pad VP3. In addition, without being limited thereto, the fifth pad VP5 may be disposed in the row direction and may be disposed between the first pad VP1 and the second pad VP2, or may be disposed on the right side of the second pad VP2.

The plurality of first voltage pads VPa and the plurality of second voltage pads VPb may be alternately disposed in either the row direction or the column direction. For example, only the plurality of first voltage applying pads VPa may be disposed in the row direction. For example, the first pad VP1 and the second pad VP2, which are the first voltage applying pads VPa, may be alternately disposed. The plurality of first voltage pads VPa and the plurality of second voltage pads VPb may be alternately disposed in the column direction. For example, the fifth pad VP5, which is the second voltage applying pad VPb, and the third pad VP3 and the fourth pad VP4, which are the first voltage applying pads VPa, may be alternately disposed, but are not limited thereto.

The plurality of voltage applying wires VL may include the plurality of first voltage applying wires VLa connected to the plurality of first voltage applying pads VPa and the plurality of second voltage applying wires VLb connected to the plurality of second voltage applying pads VPb.

The plurality of first voltage applying wires VLa may include the first wire VL1 connected to the first pad VP1, the second wire VL2 connected to the second pad VP2, the third wire VL3 connected to the third pad VP, and the fourth wire VL4 connected to the fourth pad VP4.

The plurality of second voltage applying wires VLb may include only the fifth wire VL5 connected to the fifth pad VP5.

The plurality of first voltage applying wires VLa and the plurality of second voltage applying wires VLb may be alternately disposed in only one of the row direction and the column direction, similar to the plurality of voltage applying pads VP. For example, only the first voltage applying wire VLa may be disposed in the row direction. For example, the first pad VL1 and the second pad VL2, which are the first voltage applying wires VLa, may be alternately disposed. The plurality of first voltage wires VLa and the plurality of second voltage wires VLb may be alternately disposed in the column direction. For example, the fifth wire VL5, which is the second voltage applying wire VLb, and the third wire VL3 and the fourth wire VL4, which are the first voltage applying wires VLa, may be alternately disposed, but are not limited thereto.

In this case, each of the plurality of mesa structure units MS is disposed between the plurality of intersecting voltage applying wires VL and may be connected to different voltage applying pads VP through different voltage applying wires VL.

For example, referring to FIGS. 8A to 8D, the plurality of mesa electrode units ME may be disposed on one surface of each of the plurality of mesa structure units MS. In these examples, the plurality of mesa electrode units ME may individually receive voltages from different voltage applying pads VP through different voltage applying wires VL.

The plurality of mesa electrode units ME may each include the first mesa electrodes ME1a, ME2a, ME3a, and ME4a and the second mesa electrodes ME1b, ME2b, ME3b, and ME4b. The first mesa electrodes ME1a, ME2a, ME3a, and ME4a and the second mesa electrodes ME1b, ME2b, ME3b, and ME4b may be disposed on different mesa structures among the plurality of mesa structure units MS and may be spaced apart from each other. For example, the first mesa electrodes ME1a, ME2a, ME3a, and ME4a may be disposed on one surface of the first mesa structures MS1a, MS2a, MS3a, and MS4a, and the second mesa electrodes ME1b, ME2b, ME3b, and ME4b may be disposed on one surface of the second mesa structures MS1b, MS2b, MS3b, and MS4b.

The first mesa electrodes ME1a, ME2a, ME3a, and ME4a and the second mesa electrodes ME1b, ME2b, ME3b, and ME4b are connected to different voltage applying pads VP and voltage applying wires VL so that different voltages may be applied thereto. For example, the first mesa electrodes ME1a, ME2a, ME3a, and ME4a are connected to the first voltage applying pad VPa through the first voltage applying wire VLa so that the first voltage may be applied thereto. The second mesa electrodes ME1b, ME2b, ME3b, and ME4b are connected to the second voltage applying pad VPb through the second voltage applying wire VLb so that the second voltage may be applied thereto.

That is, the first mesa electrode unit ME1 disposed on one surface of the first mesa structure unit MS1 may be connected to the first wire VL1 and the fifth wire VL5 to receive the first voltage and the second voltage.

The second mesa electrode unit ME2 disposed on one surface of a second mesa structure unit MS2 may be connected to the second wire VL2 and the fifth wire VL5 to receive the first voltage and the second voltage.

The third mesa electrode unit ME3 disposed on one surface of the third mesa structure unit MS3 may be connected to the third wire VL3 and the fifth wire VL5 to receive the first voltage and the second voltage.

The fourth mesa electrode unit ME4 disposed on one surface of the fourth mesa structure unit MS4 may be connected to the fourth wire VL4 and the fifth wire VL5 to receive the first voltage and the second voltage.

That is, the first mesa electrode unit ME1, the second mesa electrode unit ME2, the third mesa electrode unit ME3, and the fourth mesa electrode unit ME4 may share the fifth wire VL5. That is, the fifth wire VL5 may be simultaneously connected to the first mesa electrode unit ME1, the second mesa electrode unit ME2, the third mesa electrode unit ME3, and the fourth mesa electrode unit ME4 to commonly transmit the second voltage to the first mesa electrode unit ME1, the second mesa electrode unit ME2, the third mesa electrode unit ME3, and the fourth mesa electrode unit ME4, but is not limited thereto.

In some implementations, the base substrate 110 may include the plurality of insulating layers 211 that insulate different voltage applying wires VL so that each of the plurality of mesa electrode units ME may individually receive voltage through the voltage applying wires VL. For example, the plurality of insulating layers 211 may include the first insulating layer 211a, the second insulating layer 211b on the first insulating layer 211a, the third insulating layer 211c on the second insulating layer 211b, the fourth insulating layer 211d on the third insulating layer 211c, and the fifth insulating layer 211e on the fourth insulating layer 211d.

Referring to FIGS. 8A to 8D, the first insulating layer 211a may be disposed on the fifth wire VL5. The first insulating layer 211a may insulate the fifth wire VL5 and the fourth wire VL4.

The fifth wire VL5 may connect the fifth pad VP5, and the second mesa electrode ME1b of the first mesa electrode unit ME1, the second mesa electrode ME2b of the second mesa electrode unit ME2, the second mesa electrode ME3b of the third mesa electrode unit ME3, and the second mesa electrode ME4b of the fourth mesa electrode unit ME4 through the contact holes of the first insulating layer 211a, the second insulating layer 211b, the third insulating layer 211c, the fourth insulating layer 211d, and the fifth insulating layer 211e, respectively.

The fourth wire VL4 may be disposed on the fifth wire VL5 and the first insulating layer 211a. The fourth wire VL4 may connect the fourth pad VP4 and the first mesa electrode ME4a of the fourth mesa electrode unit ME4 through contact holes of the second insulating layer 211b, the third insulating layer 211c, the fourth insulating layer 211d, and the fifth insulating layer 211e.

The second insulating layer 211b may be disposed on the fourth wire VL4 and the first insulating layer 211a. The second insulating layer 211b may insulate the fourth wire VL4 and the third wire VL3.

The third wire VL3 may be disposed on the second insulating layer 211b. The third wire VL3 may connect the third pad VP3 and the first mesa electrode ME3a of the third mesa electrode unit ME3 through the contact holes of the fourth insulating layer 211d and the fifth insulating layer 211e.

The third insulating layer 211c may be disposed on the third wire VL3 and the second insulating layer 211b. The third insulating layer 211c may insulate the third wire VL3 and the second wire VL2.

The second wire VL2 may be disposed on the third insulating layer 211c. The second wire VL2 may connect the third pad VP3 and the first mesa electrode ME3a of the third mesa electrode unit ME3 through the contact hole of the fifth insulating layer 211e.

The fourth insulating layer 211d may be disposed on the second wire VL2 and the third insulating layer 211c. The fourth insulating layer 211d may insulate the second wire VL2 and the first wire VL1.

The first wire VL1 may be disposed on the fourth insulating layer 211d. The first wire VL1 may connect the fourth pad VP4 and the first mesa electrode ME4a of the fourth mesa electrode unit ME4 through the contact hole of the fifth insulating layer 211e.

The fifth insulating layer 211e may be disposed on the first wire VL1 and the fourth insulating layer 211d. The fifth insulating layer 211e may insulate the first wire VL1 and the configuration above the first wire VL1.

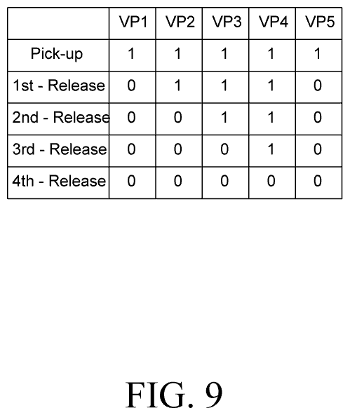

FIG. 9 is a table illustrating the voltage application logic according to the micro-LED transfer process sequence of the stamp for transferring a micro-LED according to another example implementation of the present disclosure. In FIG. 9, a case where voltage is applied to the plurality of voltage applying pads VP is indicated as 1, and a case where voltage is not applied is indicated as 0.

Referring to FIG. 9, in the pick-up process, a voltage is applied to the first pad VP1 connected to the first mesa structure unit MS1, the second pad VP2 connected to the second mesa structure unit MS2, the third pad VP3 connected to the third mesa structure unit MS3, the fourth pad VP4 connected to the fourth mesa structure unit MS4, and the fifth pad VP5 commonly connected to the first mesa structure unit MS1, the second mesa structure unit MS2, the third mesa structure unit MS3, and the fourth mesa structure unit MS4. Therefore, the micro-LEDs corresponding to each mesa structure unit MS may be picked up in batches.

Next, in the 1st-Release process, the voltage is cut off only to the first mesa structure unit MS1, so that only the micro-LED corresponding to the first mesa structure unit MS1 may be transferred. That is, the voltage of the first pad VP1 and the fifth pad VP5, which apply voltage to the first mesa structure unit MS1 through the first mesa electrode unit ME1, may be cut off.

In this case, the voltage may be continuously maintained in the mesa structure units MS except for the first mesa structure unit MS1. That is, the voltage may be continuously applied to the second pad VP2 connected to the second mesa structure unit MS2, the third pad VP3 connected to the third mesa structure unit MS3, and the fourth pad VP4 connected to the fourth mesa structure unit MS4. Accordingly, the micro-LED except for the micro-LED corresponding to the first mesa structure unit MS1 may maintain the picked-up state during the 1st-Release process.

In the 2nd-Release process, the voltage of the second mesa structure unit MS2 is removed, so that the micro-LED corresponding to the second mesa structure unit MS2 may be transferred. That is, the voltage of the second pad VP2 and the fifth pad VP5, which apply voltage to the second mesa structure unit MS2 through the second mesa electrode unit ME2, may be cut off. In this case, since the voltage of the fifth pad VP5 is already cut off in the 1st-Release process, the micro-LED corresponding to the second mesa structure unit MS2 may be transferred by cutting off only the voltage of the second pad VP2.

Meanwhile, the voltage may be continuously applied to the mesa structure units MS excluding the first mesa structure unit MS1 and the second mesa structure unit MS2. That is, voltage may be continuously applied to the third pad VP3 connected to the third mesa structure unit MS3 and the fourth pad VP4 connected to the fourth mesa structure unit MS4. Accordingly, the micro-LEDs corresponding to the third mesa structure unit MS3 and the fourth mesa structure unit MS4 may maintain a picked-up state during the 2nd-Release process.

Meanwhile, in the table of FIG. 9, it is described that the voltage is not applied to the first pad VP1 during the 2nd-Release process, but this is not limited thereto. For example, during the 2nd-Release process, voltage may be applied again to the first pad VP1 to which voltage has been cut off in the 1st-Release process. For example, there may be a micro-LED ED that is not transferred in the 1st-Release process due to a process error. When such an un-transferred micro-LED ED is transferred during the 2nd-Release process, it is inevitable that the micro-LED will be disposed to be misaligned from the normal position. Accordingly, by reapplying voltage to the first pad VP1 after the 1st-Release process so that the un-transferred micro-LED ED may be maintained in a state of being picked up by the first mesa structure unit MS1, a defect in which the un-transferred micro-LED ED in the 1st-Release process is incorrectly transferred in the 2nd-Release process may be suppressed, but is not limited thereto.

In the 3rd-Release process, the voltage of the third mesa structure unit MS3 may be removed, so that the micro-LED corresponding to the third mesa structure unit MS3 may be transferred. That is, the voltage of the third pad VP3 and the fifth pad VP5, which apply voltage to the third mesa structure unit MS3 through the third mesa electrode unit ME3, may be cut off. In this case, since the voltage of the fifth pad VP5 is already cut off in the 1st-Release process, the micro-LED corresponding to the third mesa structure unit MS3 may be transferred by cutting off only the voltage of the third pad VP3.

Meanwhile, the voltage may be continuously applied to the fourth mesa structure unit MS4 excluding the first mesa structure unit MS1, the second mesa structure unit MS2, and the third mesa structure unit MS3. That is, the voltage may be continuously applied to the fourth pad VP4 connected to the fourth mesa structure unit MS4. Accordingly, the micro-LED corresponding to the fourth mesa structure unit MS4 may maintain a picked-up state during the 2nd-Release process. In this case, since the voltage of the fifth pad VP5 is already cut off in the 1st-Release process, the micro-LED corresponding to the third mesa structure unit MS3 may be transferred by cutting off only the voltage of the fourth pad VP4.

Meanwhile, in the table of FIG. 9, it is described that voltage is not applied to the second pad VP2 during the 3rd-Release process, but this is not limited thereto. For example, during the 3rd-Release process, voltage may be applied again to the second pad VP2 to which voltage has been cut off in the 2nd release process. For example, there may be a micro-LED ED that is not transferred in the 2nd release process due to a process error. When such an un-transferred micro-LED ED is transferred during the 3rd-Release process, it is inevitable that the micro-LED will be disposed to be misaligned from the normal position. Accordingly, by re-applying voltage to the second pad VP2 after the 2nd-Release process so that the un-transferred micro-LED ED may be maintained in a state of being picked up by the second mesa structure unit MS2, a defect in which the un-transferred micro-LED ED in the 2nd-Release process is incorrectly transferred in the 3rd-Release process may be suppressed, but is not limited thereto.

Similarly, in the 3rd-Release process, the voltage may be continuously applied to the first pad VP1 to which the voltage has been applied again in the 2nd release process. Accordingly, the un-transferred micro-LED ED in the 1st-Release process may be maintained in a state of being picked up by the first mesa structure unit MS1. Accordingly, a defect in which the un-transferred micro-LED ED in the 1st-Release process is incorrectly transferred in the 3rd-Release process may be suppressed, but is not limited thereto.

In the 4th-Release process, the voltage of the fourth mesa structure unit MS4 is removed, and the transfer process may be completed by transferring the micro-LED corresponding to the fourth mesa structure unit MS4. That is, the voltage of the fourth pad VP4 and the fifth pad VP5, which apply voltage to the fourth mesa structure unit MS4 through the fourth mesa electrode unit ME4, may be cut off.

Meanwhile, in the table of FIG. 9, it is described that voltage is not applied to the third pad VP3 during the 4th-Release process, but this is not limited thereto. For example, during the 4th-Release process, voltage may be applied again to the third pad VP3 to which voltage has been cut off in the 3rd-Release process. For example, there may be a micro-LED ED that is not transferred during the 3rd-Release process due to a process error. When such an un-transferred micro-LED ED is transferred during the 4th-Release process, it is inevitable that the micro-LED will be disposed to be misaligned from the normal position. Accordingly, by re-applying voltage to the third pad VP3 after the 3rd-Release process so that the un-transferred micro-LED ED may be maintained in a state of being picked up by the third mesa structure unit MS3, a defect in which the un-transferred micro-LED ED in the 3rd-Release process is incorrectly transferred in the 4th-Release process may be suppressed, but is not limited thereto.

Similarly, in the 4th-Release process, the voltage may be continuously applied to the first pad VP1 to which the voltage has been applied again in the 2nd release process. Accordingly, the un-transferred micro-LED ED in the 1st-Release process may be maintained in a state of being picked up by the first mesa structure unit MS1. Accordingly, a defect in which the un-transferred micro-LED ED in the 1st-Release process is incorrectly transferred in the 4th-Release process may be suppressed, but is not limited thereto.

In addition, in the 4th-Release process, the voltage may be continuously applied to the second pad VP2 to which the voltage has been applied again during the 3rd-Release process. Accordingly, the un-transferred micro-LED ED during the 2nd release process may be maintained in a state of being picked up by the second mesa structure unit MS2. Accordingly, a defect in which the un-transferred micro-LED ED during the 2nd release process is incorrectly transferred during the 4th-Release process may be suppressed, but is not limited thereto.

That is, in a stamp 200 for transferring a micro-LED according to another example implementation of the present disclosure, the plurality of voltage applying wires VL and the plurality of voltage applying pads VP are individually connected to the plurality of mesa electrode units ME so that voltage may be applied individually to each mesa electrode unit ME. In general, by selectively controlling whether voltage is applied to one or more of a plurality of mesa electrode units ME, the micro-LEDs ED may be selectively transferred. For example, the voltage may be applied to all of the plurality of mesa electrode units ME so that the micro-LEDs ED may be picked up in batches. Subsequently, the voltage may be selectively cut off only to the mesa electrode unit ME of the specific mesa structure unit MS that is joined to the micro-LED ED to be released. For example, the voltage may be continuously applied only to the mesa electrode unit ME that is joined to the micro-LED ED excluding the micro-LED ED to be released. Accordingly, since the electrostatic force between the micro-LED ED that should not be released and the mesa structure unit MS is maintained, the micro-LED ED that should not be released may maintain a picked-up state. As such, the stamp 200 for transferring a micro-LED according to another example implementation of the present disclosure may minimize or reduce an over-transfer defect in which the micro-LED ED that should not be released is transferred, and may ensure that only the micro-LED ED that matches the transfer order is released to the display panel PN. Therefore, the stamp 200 for transferring a micro-LED according to another example implementation of the present disclosure may improve a transfer rate regardless of the flatness of the display panel PN.

In particular, in the stamp 200 for transferring a micro-LED according to another example implementation of the present disclosure, the first mesa electrodes ME1a, ME2a, ME3a, and ME4a, or the second mesa electrodes ME1b, ME2b, ME3b, and ME4b of the plurality of mesa electrode units ME may share the plurality of voltage applying pads VP and the plurality of voltage applying wires VL. For example, the second mesa electrode ME1b of the first mesa electrode unit ME1, the second mesa electrode ME2b of the second mesa electrode unit ME2, the second mesa electrode ME3b of the third mesa electrode unit ME3, and the second mesa electrode ME4b of the fourth mesa electrode ME4 may all be connected to the fifth pad VP5 via the fifth wire VL5 to receive (e.g., simultaneously receive) the second voltage. Accordingly, the electrostatic force between the first mesa structure unit MS1, the second mesa structure unit MS2, the third mesa structure unit MS3, and the fourth mesa structure unit MS4 and the micro-LED ED may be controlled only by controlling whether the voltage is applied to the first pad VP1, the second pad VP2, the third pad VP3, and the fourth pad VP4, which are the first voltage applying pad VPa connected to the first mesa electrode ME1a of the first mesa electrode unit ME1, the first mesa electrode ME2a of the second mesa electrode unit ME2, the first mesa electrode ME3a of the third mesa electrode unit ME3, and the first mesa electrode unit ME4a of the fourth mesa electrode ME4, respectively. That is, in the stamp 200 for transferring a micro-LED according to another example implementation of the present disclosure, the voltage application logic of the plurality of voltage pads VP may be relatively simplified. In addition, since the number of the plurality of voltage applying pads VP and the number of the plurality of voltage applying wires VL required to transfer the micro-LED ED are minimized or reduced, complication in the design of the plurality of voltage applying pads VP and voltage applying wires VL may be suppressed. That is, in the stamp 200 for transferring a micro-LED according to another example implementation of the present disclosure, the design of the voltage application logic and the plurality of voltage applying pads VP and the plurality of voltage applying wires VL may be simplified while individually controlling the electrostatic force between the plurality of mesa structure units MS and the micro-LED ED, thereby minimizing or reducing the over-transfer defect.

The example implementations of the present disclosure can also be described as follows:

According to an aspect of the present disclosure, there is provided a stamp for transferring a micro light emtting diode (LED). The stamp includes a base substrate, a plurality of voltage applying pads disposed on the base substrate, a plurality of mesa structure units disposed on the base substrate, a plurality of mesa electrode units disposed on one surface of each of the plurality of mesa structure units and a plurality of voltage applying wires connected to each of the plurality of voltage applying pads. Each of the plurality of mesa electrode units is connected to a different voltage applying wire among the plurality of voltage applying wires.

The plurality of voltage applying pads may include a plurality of first voltage applying pads that applies a first voltage, and a plurality of second voltage applying pads that applies a second voltage different from the first voltage. The plurality of first voltage applying pads and the plurality of second voltage applying pads may be alternately disposed.

The plurality of first voltage applying pads and the plurality of second voltage applying pads may be alternately disposed in both a first direction and a second direction.

The plurality of first voltage applying pads may be disposed spaced apart from each other in a first direction and a second direction. The plurality of second voltage applying pads may be disposed spaced apart from each other in the second direction. The plurality of first voltage applying pads and the plurality of second voltage applying pads may be disposed alternately in the second direction.

The plurality of voltage applying wires may be disposed to extend in a row direction and a column direction and to intersect each other. The plurality of mesa structure units may be disposed between the plurality of voltage applying wires that intersects each other.

The base substrate may include a plurality of insulating layers. The plurality of voltage applying wires may be disposed on different insulating layers from each other among the plurality of insulating layers and be insulated from each other.

The stamp may further include a plurality of rear electrodes disposed below the base substrate. The plurality of voltage applying pads may be connected to the plurality of different rear electrodes.

The plurality of mesa electrode units may include a first mesa electrode and a second mesa electrode. The second mesa electrode may be connected to the same voltage applying pad among the plurality of voltage applying pads.

According to another aspect of the present disclosure, there is provided a method for transferring a micro light emtting diode (LED). The method includes positioning a plurality of mesa electrode units of a plurality of mesa structure units on a plurality of micro-LEDs to correspond to each of the plurality of micro-LEDs, applying voltage to the plurality of mesa electrode units to pick up the plurality of micro-LEDs and selectively cutting off the voltage only to some of the plurality of mesa electrodes through a plurality of voltage applying pads connected to each of the plurality of mesa electrode units to release some of the plurality of micro-LEDs to a display panel.

The selectively cutting off of the voltage only to some of the plurality of mesa electrodes through the plurality of voltage applying pads connected to each of the plurality of mesa electrode units to release some of the plurality of micro-LEDs to the display panel may include maintaining the voltage to a remainder of the plurality of mesa electrode units.

The selectively cutting off of the voltage only to some of the plurality of mesa electrodes through the plurality of voltage applying pads connected to each of the plurality of mesa electrode units to release some of the plurality of micro-LEDs to the display panel may include adaptively controlling a voltage application to one or more of the plurality of mesa electrode units through each of the plurality of voltage applying pads.

The selectively cutting off of the voltage only to some of the plurality of mesa electrodes through the plurality of voltage applying pads connected to each of the plurality of mesa electrode units to release some of the plurality of micro-LEDs to the display panel may include eutectic bonding the plurality of micro-LEDs with a solder pattern disposed on a bank of the display panel.

Although the example implementations of the present disclosure have been described in detail with reference to the accompanying drawings, the present disclosure is not limited thereto and may be embodied in many different forms without departing from the technical concept of the present disclosure. Therefore, the example implementations of the present disclosure are provided for illustrative purposes only but not intended to limit the technical concept of the present disclosure. The scope of the technical concept of the present disclosure is not limited thereto. Therefore, it should be understood that the above-described example implementations are illustrative in all aspects and do not limit the present disclosure. All the technical concepts in the equivalent scope of the present disclosure should be construed as falling within the scope of the present disclosure.

What is claimed is:

1. A stamp for transferring a micro light emitting diode (LED), the stamp comprising:
a base substrate;
a plurality of voltage applying pads disposed on the base substrate;
a plurality of mesa structure units disposed on the base substrate;
a plurality of mesa electrode units disposed on the plurality of mesa structure units, where each mesa electrode unit of the plurality of mesa electrode units is disposed on one surface of a corresponding mesa structure unit among the plurality of mesa structure units; and
a plurality of voltage applying wires connected to the plurality of voltage applying pads, where each voltage applying wire of the plurality of voltage applying wires is connected to a corresponding voltage applying pad among the plurality of voltage applying pads,
wherein each of the plurality of mesa electrode units is connected to a different voltage applying wire among the plurality of voltage applying wires.

2. The stamp according to claim 1, wherein the plurality of voltage applying pads includes a plurality of first voltage applying pads that applies a first voltage, and a plurality of second voltage applying pads that applies a second voltage different from the first voltage, and
the plurality of first voltage applying pads and the plurality of second voltage applying pads are alternately disposed.

3. The stamp according to claim 2, wherein the plurality of first voltage applying pads and the plurality of second voltage applying pads are alternately disposed in both a first direction and a second direction.

4. The stamp according to claim 2, wherein the plurality of first voltage applying pads is disposed spaced apart from each other in a first direction and a second direction,
the plurality of second voltage applying pads is disposed spaced apart from each other in the second direction, and
the plurality of first voltage applying pads and the plurality of second voltage applying pads are disposed alternately in the second direction.

5. The stamp according to claim 1, wherein the plurality of voltage applying wires is disposed to extend in a row direction and a column direction and to intersect each other, and
each of the plurality of mesa structure units is disposed between different intersections of the plurality of voltage applying wires.

6. The stamp according to claim 1, wherein the base substrate includes a plurality of insulating layers, and
each of the plurality of voltage applying wires is disposed on a different insulating layer among the plurality of insulating layers, and the plurality of voltage applying wires are insulated from each other.

7. The stamp according to claim 6, further comprising a plurality of rear electrodes disposed below the base substrate, and
each of the plurality of voltage applying pads is connected to a different rear electrode among the plurality of rear electrodes.

8. The stamp according to claim 1, wherein each mesa electrode unit of the plurality of mesa electrode units includes a first mesa electrode and a second mesa electrode, and
the second mesa electrode of each mesa electrode unit is connected to the same voltage applying pad among the plurality of voltage applying pads.

9. A method for transferring a plurality of micro light emitting diodes (LEDs) using a plurality of mesa electrode units disposed on a plurality of mesa structure units, the method comprising:
positioning the plurality of mesa electrode units on the plurality of micro-LEDs, such that each of the plurality of mesa electrode units aligns with a corresponding micro-LED among the plurality of micro-LEDs;
applying voltage to the plurality of mesa electrode units to pick up the plurality of micro-LEDs; and
selectively cutting off the voltage only to some of the plurality of mesa electrode units through a plurality of voltage applying pads to release some of the plurality of micro-LEDs to a display panel, wherein each voltage applying pad of the plurality of voltage applying pads is connected to a corresponding mesa electrode unit among the plurality of mesa electrode units.

10. The method according to claim 9, wherein the selectively cutting off of the voltage only to some of the plurality of mesa electrode units through the plurality of voltage applying pads to release some of the plurality of micro-LEDs to the display panel comprises maintaining the voltage to a remainder of the plurality of mesa electrode units.

11. The method according to claim 9, wherein the selectively cutting off of the voltage only to some of the plurality of mesa electrodes through the plurality of voltage applying pads to release some of the plurality of micro-LEDs to the display panel comprises individually controlling a voltage application to each of the plurality of mesa electrode units through a corresponding voltage applying pad among the plurality of voltage applying pads.

12. The method according to claim 9, wherein the selectively cutting off of the voltage only to some of the plurality of mesa electrodes through the plurality of voltage applying pads to release some of the plurality of micro-LEDs to the display panel comprises eutectic bonding the plurality of micro-LEDs with a solder pattern disposed on a bank of the display panel.
